(19) United States
(12) Patent Application Publication
(10) Pub. No.: US 2003/0189463 A1
(43) Pub. Date: Oct. 9, 2003

(54) Current saving technique for charge pump based phase locked loops

(76) Inventor: Brett C. Walker, San Diego, CA (US)

Correspondence Address: Qualcomm Incorporated, Patents Department, 5775 Morehouse Drive, San Diego, CA, 92121-1714, US

(21) Appl. No.: 10/120,336

(22) Filed: Apr. 9, 2002

(51) Int. Cl. H03L 7/00

(52) U.S. Cl. 331/17

(57) ABSTRACT

A charge pump circuit includes a charge pump current source configured for differential switching of an output current and a charge pump enable switch configured to turn on the charge pump current source prior to the differential switching of the output current and to turn off the charge pump current source after the differential switching of the output current, thereby saving a significant amount of current consumption by the charge pump circuit.

### BACKGROUND OF THE INVENTION

The present invention generally relates to charge pump phase locked loop circuits and, more particularly, to a circuit for dead zone elimination in low current, low noise charge pump phase locked loops.

The phase locked loop (PLL) is well known for use in communication systems and for high speed and low noise data receivers such as data communication receivers, and high speed modems. The PLL is desirable for use in many systems because of its low cost, high integration, and easy and wide availability. The PLL may be used for demodulation in wireless communication systems, such as cellular communication systems. PLL frequency synthesizers may also be used to maintain frequency stability in wireless handsets. As the size of wireless handsets is made smaller along with the batteries that power them, the power budget for the wireless handset is reduced, creating a demand for components and circuits that draw as little current as possible.

The charge pump phase locked loop (CP-PLL) incorporating a phase-frequency detector (PFD) has been widely used in recent years because of its extended tracking range, frequency sensitive error signal, and low cost availability in integrated circuit chips. The CP-PLL is known to be capable of tracking the phase of its input signal extremely accurately. The CP-PLL derives its name from the fact that the PFD, or phase detector, output of the PLL is a current source as opposed to a voltage source and pumps current into and out of the loop filter of the PLL. The logic states of the PFD are converted into analog quantities using a charge pump. The analog quantities, i.e. currents, are passed through the loop filter of the PLL. The loop filter output controls the frequency or phase of the voltage-controlled oscillator (VCO) or current-controlled oscillator (CCO) of the PLL. For example, to increase the VCO frequency the charge pump outputs a pump up current, e.g., a source current, and to decrease the VCO frequency the charge pump outputs a pump down current, e.g., a sink current.

Charge pump based phase detectors for PLLs typically have a dead zone, where the PLL loop gain changes dramatically for very small phase error, which occurs when the PLL is either locked or close to locking. Dead zone may be due, for example, to loss of linearity in the phase detector when the phase error is small. Loss of linearity can occur, for example, when the amount of time required for delivering the correct amount of either pump up current or pump down current for the small phase error correction becomes less than the turn on/off time of the switches, or the turn on/off times of the charge pump current sources, in the charge pump circuit.

Referring to FIG. 1, an example of charge pump circuit 100, as previously implemented, is illustrated by a simplified schematic diagram showing field effect transistors (FET) 102, 104, 106,108, and 110 and bias current source 112 connected in a configuration, between a voltage source 114 and a common ground 116, so that FET 108 may act as a current source to output node 117 when pump up switch 118 is closed, or “on”, and FET 110 may act as a current sink for output node 117 when pump down switch 120 is closed, or on. Each of pump up switch 118 and pump down switch 120 is normally open, or “off”, as seen in FIG. 1, until a frequency or phase correction is required, when pump up switch 118 or pump down switch 120 (or both) may be turned on, or closed, to supply the appropriate output current for output node 117. Output node 117 may be connected to a loop filter, for example, thereby controlling the frequency or phase output of a VCO or CCO in the loop.

In normal operation, charge pump circuit 100 may have four states: 1) a pump up state, in which pump up switch 118 is on and pump down switch 120 is off, 2) a pump down state, in which pump up switch 118 is off and pump down switch 120 is on, 3) an off state in which pump up switch 118 is off and pump down switch 120 is off, and (4) a dead zone elimination state in which both pump up switch 118 is on and pump down switch 120 is on. Thus, the dead zone of charge pump circuit 100 depends on the turn on/off time of the charge pump current sources FET 108 and FET 110, which are biased by current source 112 and FETs 102, 104, and 106 to turn on when pump up switch 118 or pump down switch 120, respectively, turn on. The dead zone of charge pump circuit 100 also depends, to a lesser extent, on the turn on/off time of pump up switch 118 and pump down switch 120, which effectively delay, by a small amount, the turning on/off of charge pump current sources FET 108 and FET 110. Because of the large amount of dead zone inherent in the configuration of charge pump circuit 100, the configuration of charge pump circuit 100 produces a high noise PLL that is undesirable for application in low noise communication systems.

Referring now to FIG. 2, another example of a charge pump circuit as previously implemented, charge pump circuit 200, is illustrated by a simplified schematic diagram showing FETs 202, 204, 206, 208, and 210 and bias current source 212 connected in a configuration, between a voltage source 214 and a common ground 216, so that FET 208 may act as a current source to output node 217 when pump up switch 218 is switched to output node 217, as shown in FIG. 2, and FET 210 may act as a current sink for output node 217 when pump down switch 220 is switched to output node 217, as shown in FIG. 2. Each of pump up switch 218 and pump down switch 220 is normally switched to dump node 221, as shown in FIG. 2, until a frequency or phase correction is required, when pump up switch 218 or pump down switch 220 (or both) may be switched to output node 217 to supply the appropriate output current for output node 217. Such a switching arrangement is generally referred to as differential switching. For example, dump node 221 may provide a connection to an appropriate voltage level within charge pump circuit 200, which is capable of absorbing current from FET 208 or supplying current to FET 210. Output node 217 may be connected, for example, to a loop filter, thereby controlling the frequency or phase output of a VCO or CCO in the loop.

In normal operation, charge pump circuit 200 has four states: (1) a pump up state, in which pump up switch 218 is switched to output node 217 and pump down switch 220 is switched to dump node 221, (2) a pump down state, in which pump up switch 218 is switched to dump node 221 and pump down switch 220 is switched to output node 217, (3) a tri-state in which both pump up switch 218 is switched to dump node 221 and pump down switch 220 is switched to dump node 221, and (4) a dead zone elimination state in which both pump up switch 218 is switched to output node 217 and pump down switch 220 is switched to output node 217. Thus, charge pump current sources FET 208 and FET 210 are effectively always on, so that the dead zone of charge pump circuit 200 no longer depends on the turn on/off time of the charge pump current sources FET 208 and FET 210, but only on the turn on/off time of pump up switch 218 and pump down switch 220.

A low noise, charge pump based phase detector requires dead zone elimination to avoid variation in the loop gain of the phase locked loop once the phase locked loop is locked. Dead zone elimination may be achieved by forcing both up and down charge pump current sources, for example, FET 208 and FET 210, to act simultaneously for part of the frequency cycle of the phase detector, i.e., by placing the charge pump in the dead zone elimination state described above. The length of dead zone time required is a function of the turn on/off time of the charge pump current sources and can be a major source of noise in the PLL. Minimizing the turn on/off time and thus the dead zone time is critical to achieving low noise. Minimum turn on/off times are achieved using differential switching. Differential switching, however, has the undesirable side effect that the charge pump circuit constantly consumes current from the charge pump current sources. The current consumed is significant in low noise Integer PLLs due to the need for large phase detector gain. For example, the current consumed may comprise 50% or more of the total current drain of an integrated circuit chip containing the PLL in a cell phone handset.

As can be seen, there is a need for a low noise charge pump circuit that eliminates dead zone without consuming significant amounts of current. There is also a need for a charge pump circuit that minimizes turn on/off times for dead zone elimination while being economical of current consumption in low noise charge pump phase locked loops.

### SUMMARY OF THE INVENTION

The present invention provides a low noise charge pump circuit that eliminates dead zone without consuming significant amounts of current. The present invention also provides a charge pump circuit that minimizes turn on/off times for dead zone elimination while being economical of current consumption in low noise, charge pump phase locked loops.

In one aspect of the present invention, a charge pump circuit includes a charge pump current source configured for differential switching of an output current and a charge pump enable switch configured to turn on the charge pump current source prior to the differential switching of the output current and to turn off the charge pump current source after the differential switching of the output current.

In another aspect of the present invention, a charge pump circuit includes a current source and a current sink. The current source and the current sink are configured to provide an output current at an output node, which connects the output current to a circuit external of the charge pump circuit. The charge pump circuit also includes a dump node configured to absorb current from the current source and to supply current to the current sink; a pump up switch configured to connect the current source to the output node and to connect the current source to the dump node; a pump down switch configured to connect the current sink to the output node and to connect the current sink to the dump node so that the pump up switch and the pump down switch are configured for differential switching of the output current; and a charge pump enable switch configured to turn on the current source and the current sink prior to the differential switching of the output current.

In still another aspect of the present invention, a charge pump circuit includes a current source and a current sink configured to provide an output current to an output node which connects the output current to a loop filter of a phase locked loop. The charge pump circuit also includes a dump node configured to absorb current from the current source and to supply current to the current sink; a pump up switch configured to connect the current source to the output node and to connect the current source to the dump node; and a pump down switch configured to connect the current sink to the output node and to connect the current sink to the dump node so that the pump up switch and the pump down switch are configured for differential switching of the output current. The charge pump circuit also includes a charge pump enable switch configured to turn on the current source and the current sink for a warm up period prior to the differential switching of the output current, where the warm up period comprises an amount of time adequate for the output current to settle to a required accuracy prior to the differential switching of the output current, the warm up period is between approximately 100 ns and approximately 300 ns, the charge pump enable switch is configured to turn off the current source and the current sink after the differential switching of the output current, the charge pump enable switch is configured to switch according to a charge pump enable signal, and the charge pump enable signal is provided from a frequency divider and from a PFD in the phase locked loop.

In a further aspect of the present invention, a method for reducing current consumption in a charge pump circuit includes steps of: providing a charge pump enable signal; using the charge pump enable signal to turn on a charge pump current source prior to a charge pump event; providing an output current using the charge pump current source during the charge pump event; and turning off the charge pump current source, using the charge pump enable signal, after the charge pump event.

These and other features, aspects and advantages of the present invention will become better understood with reference to the following drawings, description and claims.

### BRIEF DESCRIPTION OF THE DRAWINGS

FIG. 1 is a simplified schematic diagram of one example of a charge pump circuit as previously implemented;

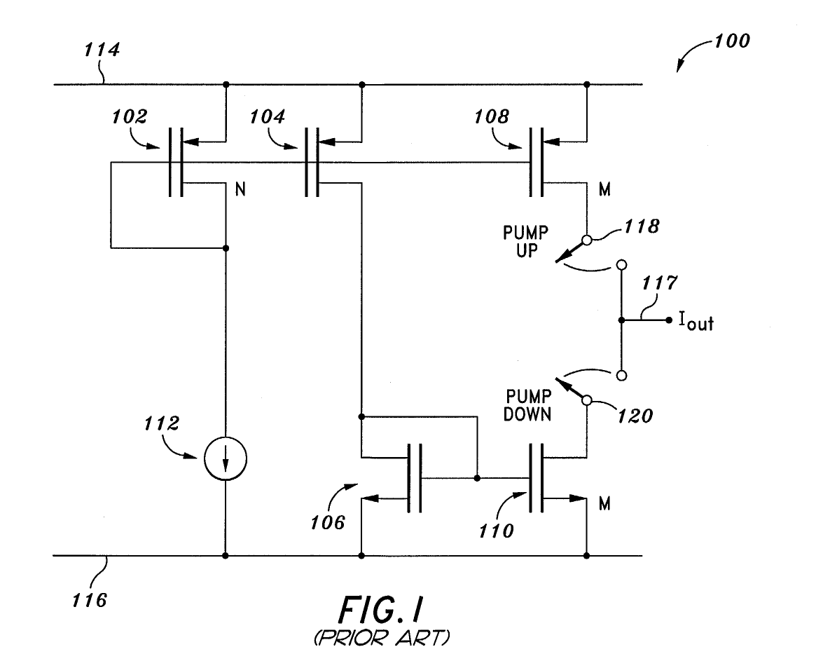

FIG. 2 is a simplified schematic diagram of another example of a charge pump circuit as previously implemented;

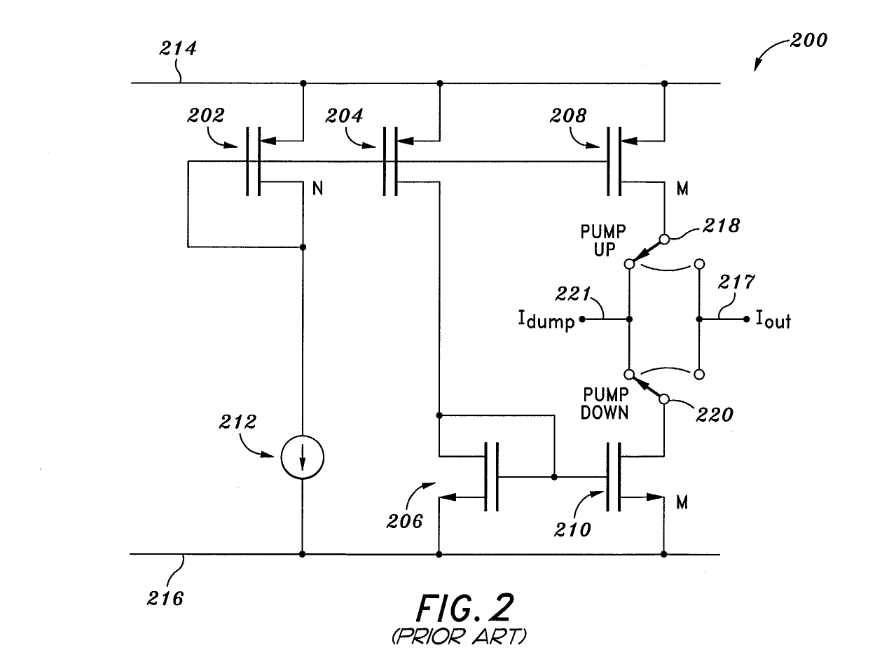

FIG. 3 is a block diagram of an exemplary phase locked loop incorporating a charge pump circuit in accordance with one embodiment of the present invention;

FIG. 4 is a simplified schematic diagram of an example of a charge pump circuit according to one embodiment of the present invention; and

FIG. 5 is a timing diagram for an example of a charge pump circuit according to one embodiment of the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

The current saving technique of the present invention may be used for low noise, charge pump (CP) based circuits where the amount of current drain in the circuit is of concern. For example, the current saving technique of the present invention may be especially useful and valuable for phase locked loops (PLL) in very large scale integrated circuit chips such as those used in cellular phone communication systems and, in particular, for integrated circuit chips used in hand-held mobile units, or cell phones.

For example, in a typical integrated circuit chip, which may use approximately 40-60 milliamps (mA) of current total, approximately 32 mA may be devoted to charge pump current drain, where the charge pump uses differential switching as known in the prior art. Thus, the charge pump current drain may amount to as much or more than 50% of the total current drain of the integrated circuit chip. Using the current saving technique of the present invention, in one embodiment where the reference frequency of the phase locked loop is 200 kilohertz (KHz), the charge pumps need only be on for approximately 200 nanoseconds (ns) out of the reference time period of 5 microseconds (μs), or less than 5% of the time. Thus, significant savings can be achieved without sacrificing the low noise properties of differential switching operation. Prior art charge pump circuits have exhibited either high noise operation or high current consumption, in contrast to the present invention, which achieves both low noise operation and economical current consumption.

In one embodiment, the present invention eliminates wasteful consumption of current by using signal available as part of the rest of the PLL to control the charge pump so that the charge pump is on only for the time required for the output current to settle to the required accuracy and the time required to provide the pump up and pump down output currents. The charge pump is turned on a short time prior to the charge pump event, i.e., a pump up or pump down input signal to the charge pump and differential switching of a pump up or pump down output current from the charge pump, so that the output current has adequate time to settle to the required accuracy. During this warm up period, the charge pump output current is sent to a dump node, as is the case for conventional differential charge pump circuits. The charge pump is turned off as soon as the charge pump event is over. The total current consumption is, therefore, reduced significantly if the charge pump warm up time is less than the reference period, i.e., the inverse of the reference frequency of the phase locked loop. Such is typically the case, as in the example given above where charge pump warm up time is less than 5% of the reference period of the phase locked loop.

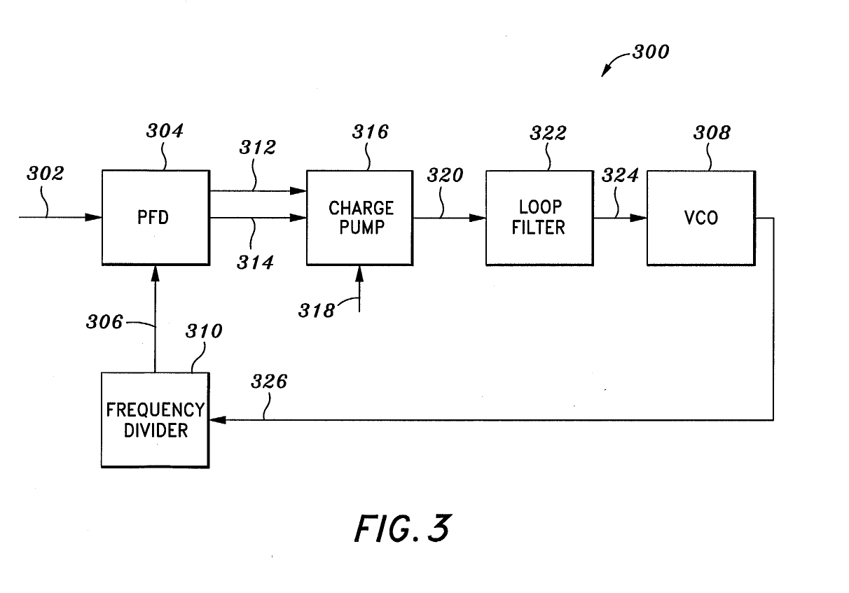

Referring now to FIG. 3, an exemplary charge pump phase locked loop 300 is illustrated according to one embodiment. Input signal 302, whose frequency and phase is to be tracked, can be fed to phase frequency detector (PFD) 304. PFD 304 can compare the frequency and phase of input signal 302 to that of local signal 306 output by voltage controlled oscillator (VCO) 308 and frequency divider 310. PFD 304 may output pump up signal 312 and pump down signal 314 to charge pump 316 at appropriate times for correcting the frequency and phase error of local signal 306, in order to cause local signal 306 to track input signal 302. Signal available as part of the rest of phase locked loop 300, i.e., charge pump enable signal 318, may be used to control charge pump 316 so that charge pump 316 is only on, or consuming current, for a minimal amount of time required to achieve frequency and phase correction. Charge pump enable signal 318 may be provided, for example, from the PLL counters in frequency divider 310. A reset signal, i.e., turning off of charge pump enable signal 318, may be provided, for example, from the internal reset signal of PFD 304, used for resetting both D flip-flops of PFD 304. Charge pump enable signal 318 may be combined from one or more other signals, for example, using appropriate logic gates, as known in the art. When enabled, for example, when charge pump enable signal 318 is high, and according to the presence of pump up signal 312 and pump down signal 314 at the inputs of charge pump 316, charge pump 316 may pump output current 320 either into or out of, respectively, loop filter 322. Loop filter output 324 may be fed to VCO 308 for controlling the frequency and phase of VCO output 326 fed to frequency divider 310.

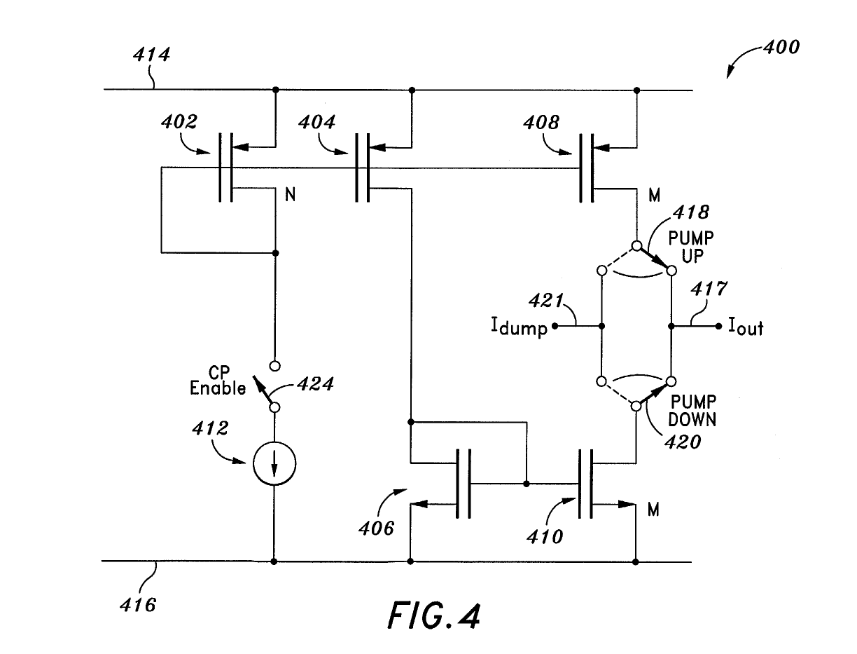

Referring now to FIG. 4, an example of a charge pump circuit according to one embodiment, charge pump circuit 400, is illustrated by a simplified schematic diagram showing field effect transistors (FET) 402, 404, 406, 408, and 410, bias current source 412, and charge pump enable switch 424 connected in a configuration, between a voltage source 414 and a common ground 416, so that, when charge pump enable switch 424 is closed, or turned on, FET 408 may act as a current source to output node 417 when pump up switch 418 is switched to output node 417, as shown in FIG. 4, and FET 410 may act as a current sink for output node 417 when pump down switch 420 is switched to output node 417, as shown in FIG. 4. Output node 417 may be connected to a circuit external to charge pump 400, for example, to a loop filter, thereby controlling the frequency or phase output of a VCO or CCO in the phase locked loop.

When charge pump enable switch 424 is closed, or turned on, charge pump circuit 400 may operate in one of four states: (1) a pump up state, in which pump up switch 418 is switched to output node 417 and pump down switch 420 is switched to dump node 421, (2) a pump down state, in which pump up switch 418 is switched to dump node 421 and pump down switch 420 is switched to output node 417, (3) a tri-state in which both pump up switch 418 is switched to dump node 421 and pump down switch 420 is switched to dump node 421, and (4) a dead zone elimination state in which both pump up switch 418 is switched to output node 417 and pump down switch 420 is switched to output node 417, as shown in FIG. 4.

As shown in FIG. 4, charge pump enable switch 424 is normally open, or turned off, so that charge pump circuit 400 consumes practically no current. When a frequency or phase correction is required, referred to above as a charge pump event, charge pump enable switch 424 may be closed, or turned on, using charge pump enable signal 318, described above. Charge pump enable signal 318 may be configured, for example, using signals available in the PLL as described above, to turn on charge pump enable switch 424 a short time, approximately 100 ns to 300 ns, before the charge pump event is to occur, in order to provide an adequate warm up period, as described above, for charge pump circuit 400. During the warm up period, charge pump circuit 400 operates in the tri-state; both pump up switch 418 and pump down switch 420 are switched to dump node 421, as shown in phantom in FIG. 4. For example, dump node 421 may provide a connection to an appropriate voltage level within charge pump circuit 400, which is capable of absorbing current from FET 408 or supplying current to FET 410.

After the warm up period, when a pump up or pump down input signal, for example, pump up signal 312 or pump down signal 314, is received by charge pump circuit 400, the appropriate one of pump up switch 418 or pump down switch 420 switches to output node 417, to supply the appropriate current into or out of, respectively, output node 417. Dead zone elimination may be achieved by forcing both up and down charge pump current sources, for example, FET 408 and FET 410, to act simultaneously for part of the frequency cycle of the phase detector, i.e., by placing the charge pump in the dead zone elimination state described above, where both pump up switch 418 is switched to output node 417 and pump down switch 420 is switched to output node 417.

After the frequency or phase correction, charge pump circuit 400 may be turned off, for example, by opening charge pump enable switch 424, a short time, for example, approximately 1 ns, after the charge pump event is over, for example, after charge pump circuit 400 has resumed tri-state operation or output current 320 has dropped to zero. Charge pump enable switch 424 may be turned off, for example, using charge pump enable signal 318 as described above. In the off state, with charge pump enable switch 424 in its normally open position, as seen in FIG. 4, charge pump circuit 400 again consumes practically no current. Thus, charge pump current sources FET 408 and FET 410 are effectively on only during the time that charge pump enable switch 424 is on, so that charge pump circuit 400 gains the low noise benefits of differential switching, without incurring the current consumption penalties of differential switching.

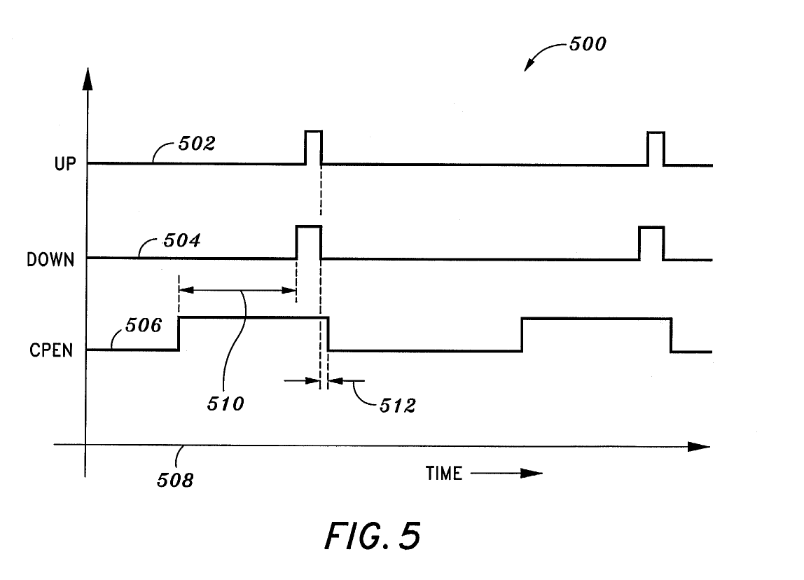

Referring now to FIG. 5, exemplary timing diagram 500 illustrates a portion of the timing relationship between charge pump enable signal 318 and output current 320. Timing diagram 500 shows pump up output current 502, pump down output current 504, and charge pump enable signal 506 graphed relative to horizontal time axis 508. Pump up output current 502 corresponds, for example, to output current 320 being pumped into loop filter 322 by charge pump 316, as shown in FIG. 3. Pump down output current 504 corresponds, for example, to output current 320 being pumped out of loop filter 322 by charge pump 316, as shown in FIG. 3. Charge pump enable signal 506 corresponds, for example, to charge pump enable signal 318 fed to charge pump 316, as shown in FIG. 3. As seen in FIG. 5, charge pump enable signal 506 is set high a short time, corresponding to warm up period 510, prior to the charge pump event represented by pump down output current 504 going high. For example, the length of warm up period 510 may preferably be in the range of approximately 100 ns to 300 ns for a PFD or PLL with a reference frequency of approximately 200 KHz. As described above, warm up period 510 may provide adequate time for the current sources of the charge pump of one embodiment to achieve output current stability.

Charge pump enable signal 506 is set low, in order to turn off charge pump 316, for example, a short time delay 512 after the completion of the charge pump event, which is represented in FIG. 5 by both pump up output current 502 and pump down output current 504 going low. Time delay 512 may be just long enough to ensure the completion of the charge pump event and settling of currents to zero, for example, approximately 1 ns.

It should be understood, of course, that the foregoing relates to preferred embodiments of the invention and that modifications may be made without departing from the spirit and scope of the invention as set forth in the following claims.

We claim:

1. A charge pump circuit comprising:
a charge pump current source configured for differential switching of an output current; and
a charge pump enable switch configured to turn on said charge pump current source prior to said differential switching of said output current.

2. The charge pump circuit of claim 1, further comprising:
a current source and a current sink, wherein said charge pump current source comprises said current source and said current sink;
an output node configured to connect said output current to a circuit external of the charge pump circuit;
a dump node configured to absorb current from said current source and to supply current to said current sink;
a pump up switch configured to connect said current source to said output node and to connect said current source to said dump node; and
a pump down switch configured to connect said current sink to said output node and to connect said current sink to said dump node.

3. The charge pump circuit of claim 1 wherein said charge pump enable switch is configured to turn on said charge pump current source for a warm up period prior to said differential switching of said output current.

4. The charge pump circuit of claim 3 wherein said warm up period comprises an amount of time adequate for said output current to settle to a required accuracy prior to said differential switching of said output current.

5. The charge pump circuit of claim 3 wherein said warm up period is between approximately 100 ns and approximately 300 ns.

6. The charge pump circuit of claim 1 wherein said charge pump enable switch is configured to turn off said charge pump current source after said differential switching of said output current.

7. The charge pump circuit of claim 1 wherein said charge pump enable switch is configured to switch according to a charge pump enable signal.

8. The charge pump circuit of claim 7 wherein said charge pump enable signal is provided from a phase locked loop.

9. The charge pump circuit of claim 7 wherein said charge pump enable signal is provided from a frequency divider and from a PFD in a phase locked loop.

10. The charge pump circuit of claim 2 wherein said output node connects said output current to a loop filter of a phase locked loop.

11. A charge pump circuit comprising:
a current source and a current sink, wherein said current source and said current sink are configured to provide an output current;
an output node configured to connect said output current to a circuit external of the charge pump circuit;
a dump node configured to absorb current from said current source and to supply current to said current sink;
a pump up switch configured to connect said current source to said output node and to connect said current source to said dump node;
a pump down switch configured to connect said current sink to said output node and to connect said current sink to said dump node wherein said pump up switch and said pump down switch are configured for differential switching of said output current; and
a charge pump enable switch configured to turn on said current source and said current sink prior to said differential switching of said output current.

12. The charge pump circuit of claim 11 wherein said charge pump enable switch is configured to turn on said current source and said current sink for a warm up period prior to said differential switching of said output current.

13. The charge pump circuit of claim 12 wherein said warm up period comprises an amount of time adequate for said output current to settle to a required accuracy prior to said differential switching of said output current.

14. The charge pump circuit of claim 12 wherein said warm up period is between approximately 100 ns and approximately 300 ns.

15. The charge pump circuit of claim 11 wherein said charge pump enable switch is configured to turn off said current source and said current sink after said differential switching of said output current.

16. The charge pump circuit of claim 11 wherein said charge pump enable switch is configured to switch according to a charge pump enable signal.

17. The charge pump circuit of claim 16 wherein said charge pump enable signal is provided from a phase locked loop.

18. The charge pump circuit of claim 16 wherein said charge pump enable signal is provided from a frequency divider and from a PFD in a phase locked loop.

19. The charge pump circuit of claim 11 wherein said output node connects said output current to a loop filter of a phase locked loop.

20. A phase locked loop comprising:
an oscillator oscillating at a frequency;
a frequency divider driven by said oscillator and providing a local signal;
a PFD, wherein said PFD compares an input signal to said local signal to provide a pump up signal and a pump down signal;
a charge pump, wherein said charge pump comprises:
a charge pump current source configured for differential switching of an output current, in response to said pump up signal and said pump down signal, and
a charge pump enable switch configured to turn on said charge pump current source prior to said differential switching of said output current; and
a loop filter, wherein said loop filter uses said output current to control said frequency of said oscillator, whereby said local signal tracks said input signal.

21. The phase locked loop of claim 20, wherein said charge pump further comprises:
a current source and a current sink, wherein said charge pump current source comprises said current source and said current sink;
an output node configured to connect said output current to said loop filter;
a dump node configured to absorb current from said current source and to supply current to said current sink;
a pump up switch configured to connect said current source to said output node and to connect said current source to said dump node; and
a pump down switch configured to connect said current sink to said output node and to connect said current sink to said dump node.

22. The phase locked loop of claim 20 wherein said charge pump enable switch is configured to turn on said charge pump current source for a warm up period prior to said differential switching of said output current.

23. The phase locked loop of claim 22 wherein said warm up period comprises an amount of time adequate for said output current to settle to a required accuracy prior to said differential switching of said output current.

24. The phase locked loop of claim 22 wherein said warm up period is between approximately 100 ns and approximately 300 ns.

25. The phase locked loop of claim 20 wherein said charge pump enable switch is configured to turn off said charge pump current source after said differential switching of said output current.

26. The phase locked loop of claim 20 wherein said charge pump enable switch is configured to switch according to a charge pump enable signal.

27. The phase locked loop of claim 26 wherein said charge pump enable signal is provided from said phase locked loop.

28. The phase locked loop of claim 26 wherein said charge pump enable signal is provided from said frequency divider and from said PFD in said phase locked loop.

29. A charge pump circuit comprising:
a current source and a current sink, wherein said current source and said current sink are configured to provide an output current;
an output node configured to connect said output current to a loop filter of a phase locked loop;
a dump node configured to absorb current from said current source and to supply current to said current sink;
a pump up switch configured to connect said current source to said output node and to connect said current source to said dump node;
a pump down switch configured to connect said current sink to said output node and to connect said current sink to said dump node wherein said pump up switch and said pump down switch are configured for differential switching of said output current; and
a charge pump enable switch configured to turn on said current source and said current sink for a warm up period prior to said differential switching of said output current, wherein said warm up period comprises an amount of time adequate for said output current to settle to a required accuracy prior to said differential switching of said output current, wherein said warm up period is between approximately 100 ns and approximately 300 ns, wherein said charge pump enable switch is configured to turn off said current source and said current sink after said differential switching of said output current, wherein said charge pump enable switch is configured to switch according to a charge pump enable signal, and wherein said charge pump enable signal is provided from a frequency divider and from a PFD in said phase locked loop.

30. A method for reducing current consumption in a charge pump circuit, comprising steps of:
providing a charge pump enable signal;
using said charge pump enable signal to turn on a charge pump current source prior to a charge pump event;
providing an output current using said charge pump current source during said charge pump event; and
turning off said charge pump current source, using said charge pump enable signal, after said charge pump event.

31. The method of claim 30 wherein said charge pump event comprises differential switching of an output current.

32. The method of claim 30 wherein said charge pump enable signal turns on said charge pump current source for a warm up period prior to said charge pump event.

33. The method of claim 32 wherein said warm up period comprises an amount of time adequate for said output current to settle to a required accuracy prior to said charge pump event.

34. The method of claim 32 wherein said warm up period is between approximately 100 ns and approximately 300 ns.

35. The method of claim 30 wherein said charge pump enable signal is provided from a phase locked loop.

36. The method of claim 30 wherein said charge pump enable signal is provided from a frequency divider and from a PFD in a phase locked loop.
